(19) United States
(12) Patent Application Publication
(10) Pub. No.: US 2004/0166627 A1
(43) Pub. Date: Aug. 26, 2004

(54) Methods for forming a capacitor on an integrated circuit device at reduced temperatures

(76) Inventors: Jae-Soon Lim, Seoul-city (KR); Sung-Tae Kim, Gyeonggi-do (KR); Young-Sun Kim, Gyeonggi-do (KR); Ki-Hyun Hwang, Gyeonggi-do (KR); Gab-Jin Nam, Gyeonggi-do (KR); Ki-Chul Kim, Gyeonggi-do (KR); Joo-Won Lee, Gyeonggi-do (KR); Jae-Young Park, Gyeonggi-do (KR)

Correspondence Address: MYERS BIGEL SIBLEY & SAJOVEC, PO BOX 37428, RALEIGH, NC, 27627, US

(21) Appl. No.: 10/629,407

(22) Filed: Jul. 29, 2003

(30) Foreign Application Priority Data
Feb. 25, 2003 (KR) 2003-11794

(51) Int. Cl. H01L 21/8242

(52) U.S. Cl. 438/241; 438/253; 438/396

(57) ABSTRACT

Methods of forming a capacitor on an integrated circuit include forming a lower electrode of the capacitor on an integrated circuit substrate. A protection layer is formed on the lower electrode at a temperature below a minimum temperature associated with a phase change of the lower electrode. A dielectric layer is formed on the protection layer. The protection layer is configured to limit oxidation of the lower electrode during forming of the dielectric layer. An upper electrode of the capacitor is formed on the dielectric layer.

### RELATED APPLICATION

This application claims priority to Korean Patent Application 2003-11794, filed on Feb. 25, 2003, the contents of which are herein incorporated by reference in their entirety.

### BACKGROUND OF THE INVENTION

The present invention relates to methods for manufacturing integrated circuit devices and more particularly to methods of forming a capacitor on an integrated circuit device.

Various integrated circuit devices, including semiconductor memory devices, include one or more capacitors fabricated (manufactured) on the integrated circuit substrate. There is a growing need to increase the capacitance within a limited area as integrated circuit (semiconductor) devices become more highly integrated. Various approaches have been proposed to provide a desired capacitance in a more limited space, for example, to provide increased density of memory cells in an integrated circuit memory device. One proposed approach is a thinning method for reducing the thickness of a dielectric layer. A second approach includes increasing the surface area of an electrode by using a three-dimensional electrode, such as cylinder-type electrode or a fin-type electrode. Another approach is to grow hemispherical grains (HSG) on the surface of an electrode. A further alternative approach is to use a dielectric layer of a high dielectric material having a dielectric constant which is significantly greater than that of a conventional oxide/nitride/oxide (ONO) dielectric.

Dynamic random access memory (DRAM) devices in an integrated circuit device may include one access transistor and one storage capacitor for a cell. As a practical matter for such devices, increasing the storage capacity of the capacitor while maintaining a horizontal area that the capacitor occupies on a substrate may become difficult.

As is generally known, the storage capacity of the capacitor C may be represented by the following Equation 1.

C=ε₀ε×A/d Equation 1

In Equation 1, the parameters ε₀ and ε, respectively, are a dielectric constant in vacuum and a dielectric constant of a dielectric layer of a capacitor. The parameter A is the effective area of the capacitor and d is the thickness of the dielectric layer. Thus, Equation 1 indicates that methods for increasing the storage capacity of a capacitor can include forming a dielectric layer having a high dielectric constant, increasing an effective area of the capacitor, reducing a thickness of the dielectric layer, forming a dielectric layer using a ferroelectric material, and the like.

For approaches using metal oxides having a high dielectric constant, the selected material may be one or more of Ta₂O₅, TiO₂, Al₂O₃, Y₂O₃, ZrO₂, HfO₂, BaTiO₃, SrTiO₃, and the like. An example of a capacitor having a dielectric layer including such a metal oxide having a high dielectric constant is described in U.S. Pat. No. 5,316,982 issued to Taniguchi.

A dielectric layer using metal oxide having a high dielectric constant may be formed under an oxygen atmosphere. Under such condition, during forming of the dielectric layer, an oxide layer may be formed at an interface between the dielectric layer and a lower electrode due to the oxygen atmosphere. When such an oxide layer is formed at the interface between the dielectric layer and the lower electrode, the storage capacity of the resulting capacitor may be lowered.

To address this problem, a nitride layer may be formed on the lower electrode before forming the dielectric layer. The nitride layer may prevent the formation of the oxide layer between the dielectric layer and the lower electrode. The nitride layer may also prevent a possible reaction between the dielectric layer and the lower electrode. The nitride layer is typically formed by a rapid thermal nitration (RTN) process. For example, a polysilicon layer may be formed as the lower electrode and the surface portion of the polysilicon layer may be nitrated by the rapid thermal nitration process to form the nitride layer. The rapid thermal nitration process is typically carried out at a temperature of about 700° C. or more.

Because the rapid thermal nitration uses a temperature of about 700° C. or more, a thermal budget is generally imposed on the lower electrode or a contact portion of a metal wiring layer. The thermal budget applied to the lower electrode or the contact portion may cause a reduction in the functional characteristics of a resulting capacitor and, in turn, of the integrated circuit device.

To reduce the problems of rapid thermal nitration, it has been proposed to use a method of forming the nitride layer on the lower electrode at a lower temperature instead of using the rapid thermal nitration method. Examples of processes for forming the nitride layer on the lower electrode at the lower temperature are described in Korean Laid-Open Patent Publication Nos. 2002-32285 & 1999-55201. As described in these disclosures, a method of forming the nitride layer on the lower electrode includes using a plasma nitration method and then forming Ta₂O₅ dielectric layer. When the Ta₂O₅ layer is formed as the dielectric layer, a heat treatment should be provided following formation of the Ta₂O₅ layer. The heat treatment may crystallize the Ta₂O₅ layer and impurities may be removed. However, the heat treatment is typically implemented at a temperature of about 700° C. or more. As a result, the lower electrode may receive thermal damage during the heat treatment process and the functional characteristics of the capacitor may be reduced. Thus, when the capacitor is formed by either of these conventional methods, various problems due to the formation of an oxide layer or a thermal damage may be encountered.

### SUMMARY OF THE INVENTION

In some embodiments of the present invention, methods of forming a capacitor on an integrated circuit include forming a lower electrode of the capacitor on an integrated circuit substrate. A protection layer is formed on the lower electrode at a temperature below a minimum temperature associated with a phase change of the lower electrode (i.e., below the lowest temperature causing a phase change). A dielectric layer is formed on the protection layer. The protection layer is configured to limit oxidation of the lower electrode during forming of the dielectric layer. An upper electrode of the capacitor is formed on the dielectric layer.

In other embodiments of the present invention, first lower electrode is an amorphous silicon layer, a polycrystalline silicon layer and/or a composite layer thereof. The protection layer may be a nitride layer. The upper electrode may be an amorphous silicon layer, a polycrystalline silicon layer, a Ru layer, a Pt layer, an Ir layer, a TiN layer, a TaN layer, a WN layer and/or a composite layer thereof.

In further embodiments of the present invention, forming the protection layer includes forming the nitride layer at a temperature of about 600° C. or less using a plasma nitration process. In other embodiments of the present invention, forming the protection layer includes forming the nitride layer at a temperature of about 600° C. or less using a chemical vapor deposition process and/or an atomic layer deposition process. In alternative embodiments of the present invention, forming the protection layer includes forming the nitride layer at a temperature of about 600° C. or less using a microwave-type deposition process.

In other embodiments of the present invention, the dielectric layer is a metal oxide layer. The metal oxide layer may be a TiO₂ layer, an Al₂O₃ layer, an Y₂O₃ layer, a ZrO₂ layer, an HfO₂ layer, a BaTiO₃ layer, a SrTiO₃ layer and/or a composite layer thereof. Forming the dielectric layer may include forming the metal oxide layer at a temperature of about 600° C. or less using a chemical vapor deposition process and/or an atomic layer deposition process.

In further embodiments of the present invention, the lower electrode is a cylindrical lower electrode. In such embodiments, forming a lower electrode includes forming a lower structure on the integrated circuit substrate. An insulation layer pattern having a contact hole is formed on the lower structure. A conductive plug is formed in the contact hole. An oxide layer patterned to have a cylindrical shape is formed on the insulation layer pattern and the plug. A conductive layer for the lower electrode is formed on the oxide layer and the oxide layer is removed to form the cylindrical lower electrode. Forming the protection layer may include forming the protection layer on the cylindrical lower electrode.

In yet further embodiments of the present invention, methods of forming a capacitor are provided. A first conductive layer is formed on a substrate. Then, a reaction-preventing layer is formed on the first conductive layer to prevent an oxidation at a temperature of not generating a phase change of the first conductive layer. A dielectric layer is formed on the reaction-preventing layer and a second conductive layer is formed on the dielectric layer.

Embodiments of the present invention also provide other methods of forming a capacitor. First, an insulation layer pattern having a contact hole is formed on a substrate having a lower structure. Then, a first conductive layer is continuously on a sidewall portion and a bottom portion of the contact hole and on the surface of the insulation layer pattern. The first conductive layer formed on the surface portion of the insulation layer pattern is removed and the insulation layer pattern is removed to allow the first conductive layer to remain on the side wall portion and the bottom portion of the contact hole to form a cylindrical lower electrode. After that, a reaction-preventing layer is formed on the cylindrical lower electrode for preventing an oxidation at a temperature of not generating a phase change of the lower electrode. A dielectric layer is formed on the reaction-preventing layer and a second conductive layer is formed on the dielectric layer as an upper electrode.

As described above, a reaction-preventing layer is formed at a low temperature that does not generate a phase change of the lower electrode. Therefore, a thermal budget applied onto the lower electrode during forming of the reaction-preventing layer can be significantly reduced in some embodiments of the present invention. In addition, for some embodiments of the present invention, the method can be used for forming a capacitor having a high storage capacity by applying metal oxide having a high dielectric constant to form a dielectric layer.

### BRIEF DESCRIPTION OF THE DRAWINGS

FIGS. 1A to 1D are cross-sectional views illustrating methods of forming a capacitor of an integrated circuit device according to some embodiments of the present invention;

FIGS. 2A to 2G are cross-sectional views illustrating methods of forming a cylindrical capacitor of an integrated circuit device according to some embodiments of the present invention; and

FIG. 3 is a graph illustrating contact resistance of a capacitor formed according to some embodiments of the present invention.

### DETAILED DESCRIPTION

The present invention now will be described more fully hereinafter with reference to the accompanying drawings, in which preferred embodiments of the invention are shown. This invention may, however, be embodied in many different forms and should not be construed as limited to the embodiments set forth herein; rather, these embodiments are provided so that this disclosure will be thorough and complete, and will fully convey the scope of the invention to those skilled in the art. Like numbers refer to like elements throughout. It will be understood that when an element is referred to as being “on” or “connected to” or “coupled to” another element, it can be directly on, connected to or coupled to the other element or intervening layers or elements may also be present. In contrast, when an element is referred to as being “directly on” or “directly connected to” or “directly coupled to” another element, there are no intervening layers or elements present. The relative thickness of layers in the illustrations may be exaggerated for purposes of describing the present invention.

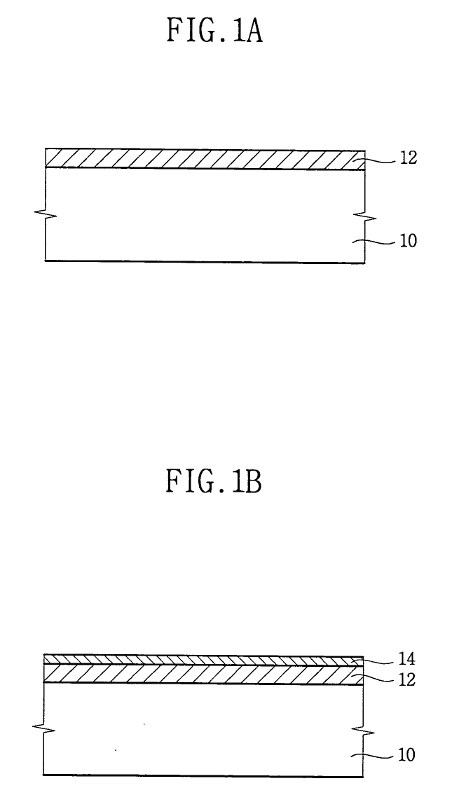

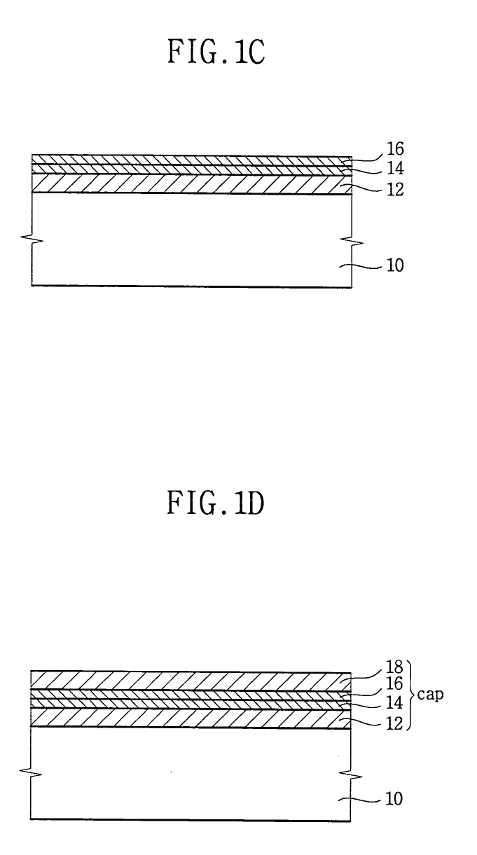

The present invention will now be further described with reference to the embodiments illustrated in the figures. FIGS. 1A through 1D are cross-sectional views illustrating methods of forming a capacitor of an integrated circuit (semiconductor) device according to some embodiments of the present invention. As shown in FIG. 1A, a first conductive layer 12 is formed on an integrated circuit (semiconductor) substrate 10. The first conductive layer 12 defines a lower electrode of a capacitor in an integrated circuit device. For example, the first conductive layer 12 may be an amorphous silicon layer, a polycrystalline silicon layer, or the like. In some embodiments of the present invention, the first conductive layer 12 is a single layer structure formed of only one of these materials. However, in other embodiments of the present invention, two or more layers, such as an amorphous silicon layer, a polycrystalline silicon layer, and/or the like, are deposited to form a multi-layered structure (i.e., the first conductive layer 12 may be a composite layer).

Referring to FIG. 1B, a reaction-inhibiting protective layer 14 (also referred to herein as reaction-preventing) is formed on the first conductive layer 12. The reaction-preventing protective layer 14 inhibits or prevents the formation of an oxide layer at an interface between the first conductive layer 12 and a subsequently formed dielectric layer during forming of the dielectric layer. In addition, the reaction-inhibiting protection layer 14 may also facilitate the reaction of the first conductive layer 12 with the dielectric layer. In some embodiments of the present invention, the reaction-inhibiting protection layer 14 may be a nitride layer mentioned.

When the reaction-inhibiting protection layer 14 is formed at a high temperature, the phase of the first conductive layer 12 may be changed, which, in turn, may cause a resistance problem. Therefore, in some embodiments of the present invention the reaction-inhibiting protection layer 14 is formed at a temperature condition that is selected to not cause a phase change of the first conductive layer 12 and to not substantially affect a contact resistance of the device.

When a nitride layer is formed on the first conductive layer 12 as the reaction-inhibiting protection layer 14, the first conductive layer 12 is an amorphous silicon layer and the temperature during forming of the nitride layer is up to about 700° C., the amorphous silicon may be transformed into crystalline silicon. Thus, when the temperature during forming of the nitride layer exceeds about 600° C., the phase of the first conductive layer 12 generally changes. As a result, in some embodiments of the present invention, the nitride layer is formed at a temperature of about 600° C. or less.

In some embodiments of the present invention, the nitride layer is formed by a plasma nitration method at a temperature of about 600° C. or less, by a chemical vapor deposition method at a temperature of about 600° C. or less and/or by an atomic layer deposition method at a temperature of about 600° C. or less.

Embodiments of methods of forming the nitride layer by the plasma nitration method at a temperature condition of about 600° C. or less will now be further described. First, the temperature of the inner portion of a processing chamber is set to about 600° C. NH₃ gas or N₂ gas is then provided into the processing chamber and plasma is applied to the NH₃ gas or the N₂ gas. Nitration occurs at the surface portion of the first conductive layer 12 to form a nitride layer on the first conductive layer 12.

The nitride layer may be formed at a temperature of about 600° C. or less because a kinetic energy is applied as well as a thermal energy. For a typical conventional rapid thermal nitration method, only thermal energy is utilized and so the temperature is generally set to about 700° C. or more. In contrast, for various embodiments of the present invention using the plasma nitration method, a temperature of up to about 600° C. is sufficient. Therefore, the thermal energy from the temperature difference during application of the plasma nitration method is complementary to kinetic energy. In particular, using the plasma nitration method, the kinetic energy by the plasma is also applied in addition to the thermal energy.

Embodiments of methods of forming the nitride layer by the chemical vapor deposition method at a temperature condition of about 600° C. or less will now be further described. First, the temperature of the inner portion of the processing chamber is set to about 550° C. The processing chamber is provided with a gas including silicon and a gas including nitrogen as a gas source. The gas including silicon and the gas including nitrogen are excited utilizing plasma. The gas including silicon and the gas including nitrogen are then reacted with each other to form a nitride compound. The formed nitride compound is deposited on the first conductive layer 12. The deposition is continued until a nitride layer having an appropriate thickness is obtained. Thus, the formation of the nitride layer as the reaction-inhibiting protection layer 14 by the chemical vapor deposition method is accomplished by a repeated deposition of the nitride compound rather than through a nitration of the surface portion of the first conductive layer 12. For the chemical vapor deposition process, again, a temperature condition of about 600° C. or less is used.

Embodiments of methods of forming the nitride layer by the atomic layer deposition method at a temperature condition of about 600° C. or less will now be further described. The temperature of the inner portion of a processing chamber is set to about 550° C. A first reacting material is then introduced into the processing chamber. A source gas including silicon can be used as the first reacting material. When introducing the first reacting material, a portion of the first reacting material is chemically absorbed (referred to as chemisorbed) on the first conductive layer 12.

Subsequently, an inert gas is introduced into the processing chamber. Through the introduction of the inert gas, the first reacting material physically absorbed (referred to as physisorbed) on the first conductive layer 12 is removed. An example of a suitable inert gas is argon. The first reacting material is removed by purging using the inert gas and/or by vacuum pumping. The purging and/or the vacuum pumping can be independently applied. However, the purging and the vacuum pumping in some embodiments of the present invention are sequentially applied. The physically absorbed first reacting material is removed from the first conductive layer 12 through the purging and/or vacuum pumping processes as described above.

A second reacting material is introduced into the processing chamber. The second reacting gas may be a source gas including nitrogen. When the first reacting material is the source gas including silicon, the second reacting gas may be the source gas including nitrogen. When the first reacting material is the source gas including nitrogen; the second reacting gas may be the source gas including silicon. By introducing the second reacting material, a portion of the second reacting material is chemically absorbed onto the first conductive layer 12.

Subsequently, an inert gas is introduced into the processing chamber. As a result of introducing the inert gas, the second material physically absorbed onto the first conductive layer 12 is removed. Again, the inert gas may be argon. The removal of the second reacting material may be accomplished through a purging process utilizing the inert gas and/or a vacuum pumping process as described above for the first reacting material. As is also described above with reference to the first reacting material, the physically absorbed second reacting material is removed from the first conductive layer 12 through the purging and/or vacuum pumping.

As a result, the first reacting material and the second reacting material are chemically absorbed onto the first conductive layer 12. That is, a solid material including the first reacting material and the second reacting material is formed on the first conductive layer 12. Through repeating the steps of introducing the first reacting material, purging (and/or selectively vacuum pumping), introducing the second reacting material and purging (and/or selectively vacuum pumping), a nitride layer is formed as the reaction preventing protection layer 14 on the first conductive layer 12. A nitride layer having a desired thickness can be obtained by controlling the number of repeat times of the above-described sub-processes.

Using the nitride layer as the reaction preventing protective layer 14 formed by the atomic layer deposition method, a nitride layer having a thickness of from about several Π to about several tens of Π can be advantageously formed. Accordingly, in some of the preferred embodiments of the present invention, the reaction-inhibiting protection layer 14 is formed through the atomic layer deposition method.

In addition to the plasma nitration method, the chemical vapor deposition method and the atomic layer deposition method, a microwave-type deposition method can be used to form the nitride layer in some embodiments of the present invention. As a kinetic energy is also generated through the microwave-type deposition method, the processing temperature condition of about 600° C. or less can also be used.

Referring now to FIG. 1C, a dielectric layer 16 is formed on the reaction-inhibiting protection layer 14. The dielectric layer 16 can be a metal oxide layer. Thus, the dielectric layer 16 is formed under an oxygen atmosphere. However, given the protection layer 14, the first conductive layer 12 (i.e. a lower electrode) is not significantly reactive under the oxygen atmosphere during formation of the dielectric layer 16. Thus, the reaction-inhibiting protection layer 14 shields the lower electrode from the oxygen atmosphere. The dielectric layer 16 can be a metal oxide layer including a TiO₂ layer, a Al₂O₃ layer, a Y₂O₃ layer, a ZrO₂ layer, a HfO₂ layer, a BaTiO₃ layer, a SrTiO₃ layer and/or the like. In some embodiments of the present invention, one of these layers is used alone. However, two or more layers can be sequentially deposited to form a composite layer. In some embodiments of the present invention, the metal oxide layer formed as the dielectric layer is not a Ta₂O₅ layer because a crystallization and heat treatment should generally be applied at about 600° C. or over after forming a Ta₂O₅ layer.

According to some embodiments of the present invention, a process for post-treating the dielectric layer 16 is not used after forming the metal oxide layer as the dielectric layer 16. In various embodiments of the present invention, the dielectric layer 16 is a metal oxide layer formed by a chemical vapor deposition method at a temperature of about 600° C. or less or by an atomic layer deposition method at a temperature of about 600° C. or less.

Embodiments of methods of forming the dielectric layer 16 by the chemical vapor deposition method at a temperature condition of about 600° C. or less will now be further described. First, the temperature of the inner portion of a processing chamber is set to about 600° C. A source gas is then provided into the processing chamber. The source gas is selected based on the kind of a thin film to be formed. For example, a gas including aluminum (Al) and a gas including oxygen (O) may be provided to the processing chamber to form an aluminum oxide (Al₂O₃) layer.

The gas source is excited using plasma. As a result, a reaction product of the gas sources is deposited on the reaction-inhibiting protection layer 14. A dielectric layer 16 having a predetermined thickness is formed on the reaction-inhibiting protection layer 14 based on a duration of the process.

Embodiments of methods of forming the dielectric layer 16 by the atomic layer deposition method at a temperature condition of about 600° C. or less will now be further described. First, the temperature of the inner portion of the processing chamber is set to about 600° C. or less and, in some embodiments, to about 450° C. Then, a third reacting material is introduced into the processing chamber. The third reacting material is selected based on the kind of the thin film to be formed. When forming a metal oxide layer, the third reacting material may include a metal precursor. A portion of the introduced third material is chemically absorbed on the reaction-inhibiting protection layer 14.

Subsequently, an inert gas is introduced into the processing chamber. The inert gas removes a physically absorbed portion of the third reacting material from the reaction-inhibiting protection layer 14. The inert gas may be argon. The removal of the third reacting material may be accomplished by a purging process utilizing the inert gas and/or by a vacuum pumping process. The purging and/or the vacuum pumping can be independently applied. However, the purging and the vacuum pumping in some embodiments of the present invention are sequentially applied. The physically absorbed third reacting material is removed from the reaction-inhibiting protection layer 14 by the purging and/or vacuum pumping.

A fourth reacting material is introduced into the processing chamber. The fourth reacting material may be an oxidizing agent. A portion of the second reacting material is chemically absorbed onto the reaction-inhibiting protection layer 14 in the processing chamber.

An inert gas is then introduced into the processing chamber. The inert gas may remove physically absorbed fourth reacting material on the reaction-inhibiting protection layer 14. The inert gas may be argon. The fourth reacting material may be removed by a purging process utilizing the inert gas and/or a vacuum pumping as described previously for removal of the third reacting material. The purging and/or the vacuum pumping can be independently applied. However, the purging and the vacuum pumping in some embodiments of the present invention are sequentially applied. The physically absorbed fourth material is removed from the reaction-inhibiting protection layer 14 by the purging and/or vacuum pumping.

As a result, the third reacting material and the fourth reacting material are chemically absorbed onto the reaction-inhibiting protection layer 14. In other words, a solid material including the third reacting material and the fourth reacting material is formed on the reaction-inhibiting protection layer 14. By repeating the processes of introducing the third reacting material, the purging (and selectively vacuum pumping), the introducing of the fourth material and purging (and selectively vacuum pumping), and the purging (and selectively vacuum pumping), the dielectric layer 16 is formed on the reaction preventing layer 14. The thickness of the dielectric layer 16 may be formed to a desired level by controlling the number of repeat times for these operations.

Referring now to FIG. 1D, a second conductive layer 18 is formed on the dielectric layer 16 to provide an upper electrode of a capacitor. The second conductive layer 18 can be, for example, an amorphous silicon layer, a polycrystalline silicon layer, a Ru layer, a Pt layer, an Ir layer, a TiN layer, a TaN layer, a WN layer, and the like. One of these layers may be used alone to provide a single layer structure. However, two or more layers can be sequentially deposited to form a multi-layered composite layer.

After completing the above-described processes, a capacitor including the lower electrode 12, the dielectric layer 16 and the upper electrode 18 is formed on the substrate 10. The capacitor is designated as “cap” in FIG. 1D.

As described above for various embodiments of the present invention, the reaction-inhibiting protection layer 14 is formed between the lower electrode 12 and the dielectric layer 16. The dielectric layer 16 can be a metal oxide layer having a high dielectric constant. As detailed above, all of the described processes for forming the capacitor are implemented at a temperature of about 600° C. or less. As the process for forming the capacitor is carried out at such a lower temperature, thermal damage due to the processing temperature during forming of the capacitor can be significantly decreased in some embodiments of the present invention. Therefore, deterioration of functional characteristics of the capacitor induced by thermal damage can be reduced and reliability of the capacitor may be improved.

In the embodiments described above, the capacitor is shown as a simple plate type capacitor. However, it is to be understood that the methods of the present invention may be applied to other types of capacitors having a cylindrical shape, a pin shape, and so on.

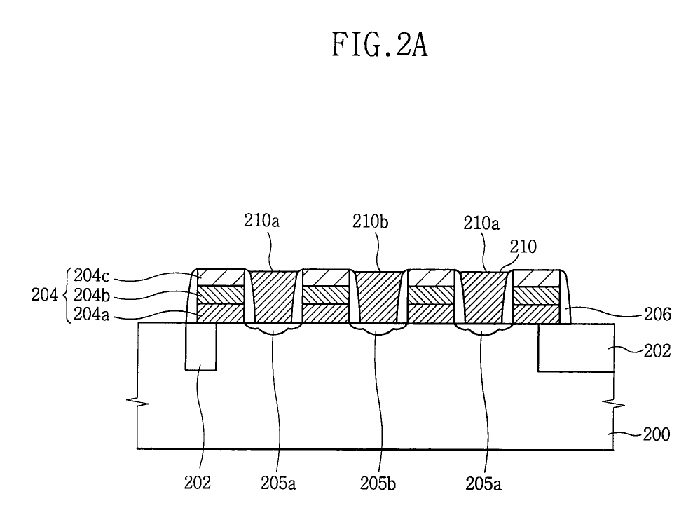

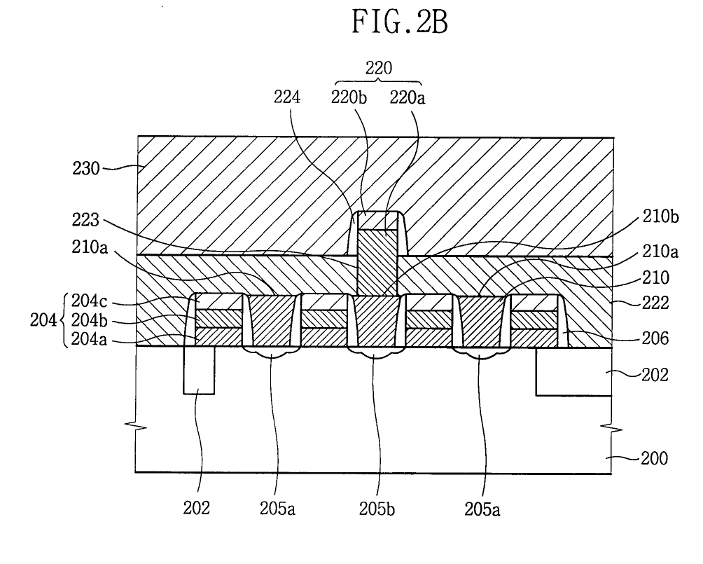

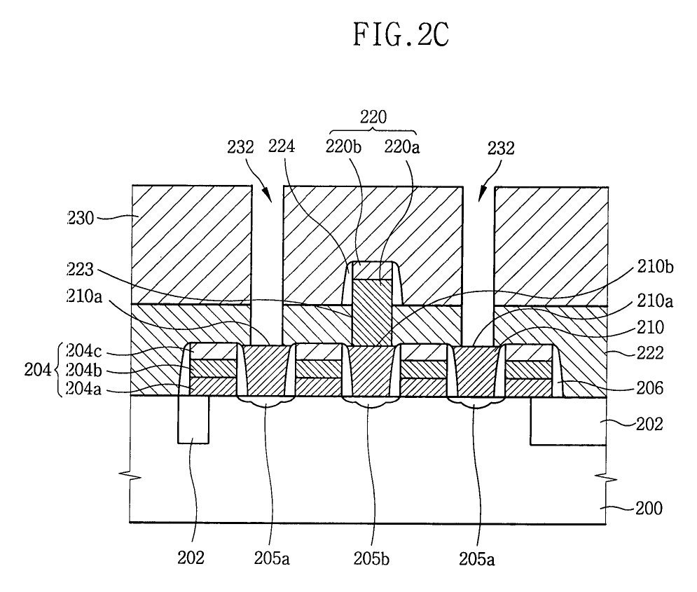

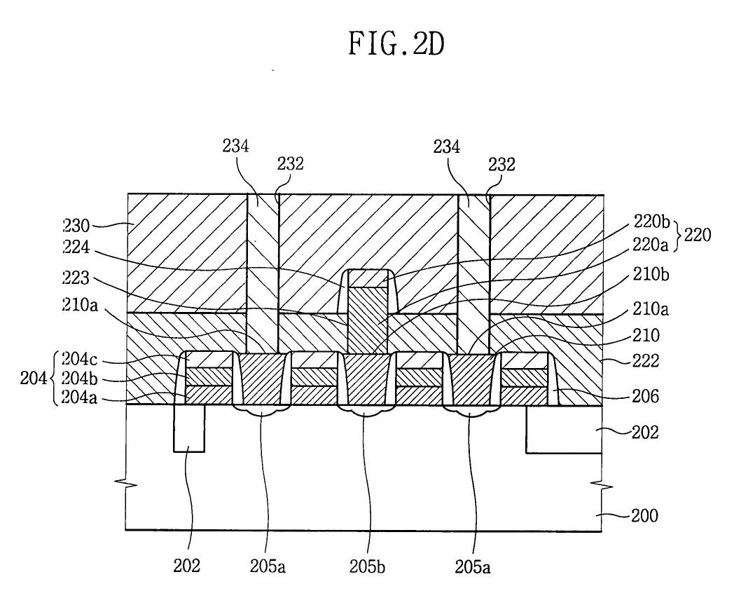

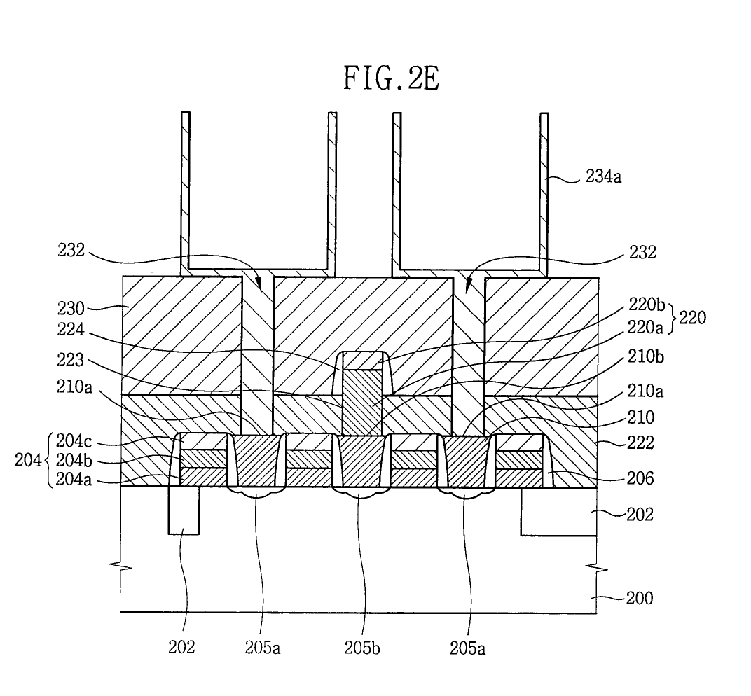

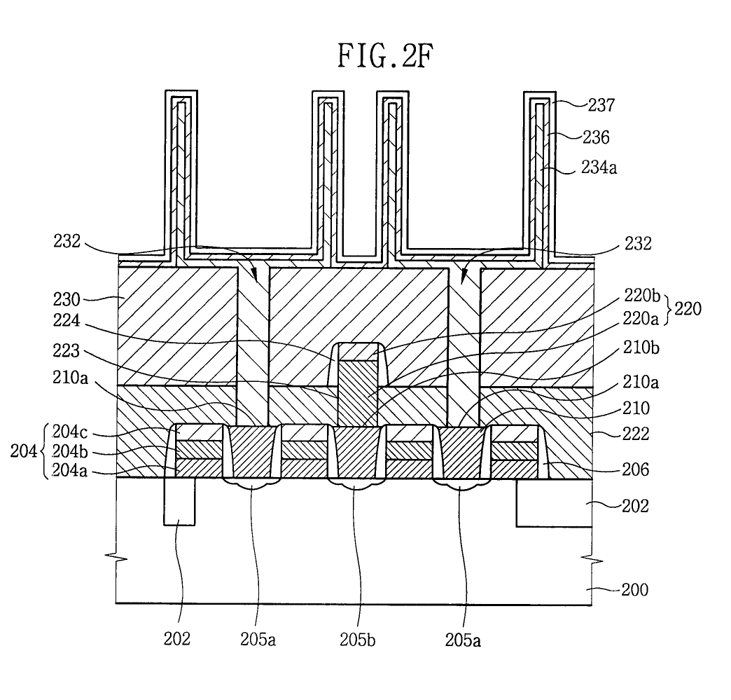

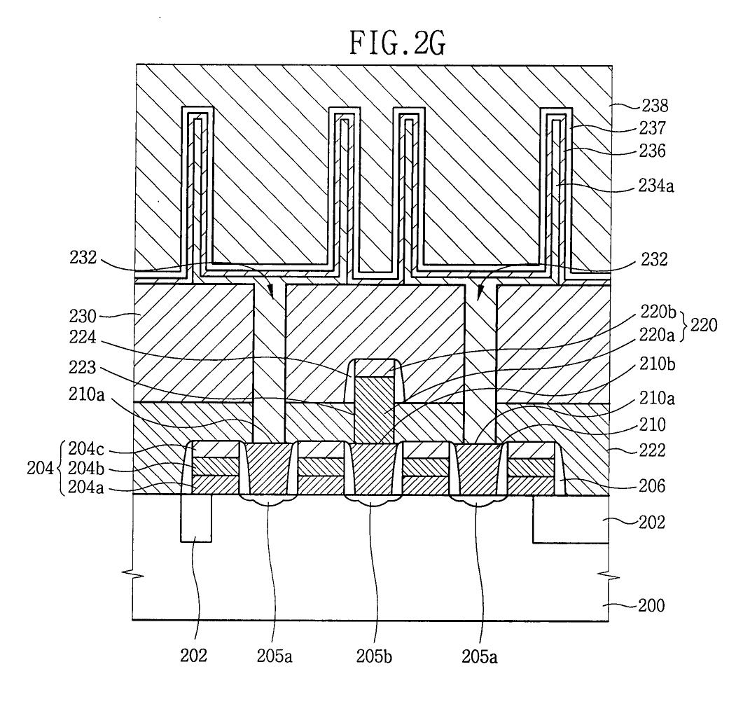

A method of forming a cylindrical capacitor of an integrated circuit device according to some embodiments of the present invention will now be described with reference to the cross-sectional views of FIGS. 2A-2G. As shown in FIG. 2A, a trench structure 202 is formed at an upper portion of an integrated circuit (semiconductor) substrate 200, for example, through an isolation process. Thus, the substrate 200 is separated into an active region and a non-active (field) region. A p-well and an n-well are formed by partially implanting impurities into the substrate 200. Gate patterns 204, shown in FIG. 2A as including a polysilicon 204a, a tungsten silicide 204b and a silicon nitride 204c, are formed on the active region of the substrate 200.

For the integrated circuit device of FIGS. 2A to 2G, the gate pattern 204 provides word lines of a DRAM device. The gate pattern 204 includes a polycide structure formed by stacking the impurity-doped polysilicon 204a and the tungsten suicide 204b. As shown in FIG. 2A, a spacer 206 of silicon nitride may be formed on the sidewall portion of the gate pattern 204.

Impurities are implanted into the upper portion of the substrate 200 neighboring the gate patterns 204 utilizing the gate patterns 204 as a mask to form a source 205a and a drain 205b. Thus, a transistor structure including the gate pattern 204, the source 205a and the drain 205b is provided. For the memory device structure of FIG. 2A, one of the source 205a and the drain 205b of the transistor structure is a capacitor contact region for connecting to a lower electrode of the capacitor and the other is a bit line contact region for connecting to a bit line structure. In some embodiments of the present invention, the source 205a corresponds to the capacitor contact region and the drain 205b corresponds to the bit line contact region.

A capacitor contact pad 210a for electrically connecting the lower electrode of the capacitor to the source 205a and a bit line contact pad 210b for electrically connecting the bit line structure to the drain 205b are formed by filling polysilicon between gate patterns 204 of the transistor structure. Thus, as shown in FIG. 2A, the polysilicon 210 filled in the capacitor contact region corresponds to the capacitor contact pad 210a and the polysilicon 210 filled in the bit line contact region corresponds to the bit line contact pad 210b.

Referring now to FIG. 2B, a bit line.structure 220 electrically contacting the bit line contact pad 210b to the drain 205b is formed. As shown for the embodiments of FIG. 2B, a first interlayer dielectric 222 is deposited on the gate pattern 204 of the transistor structure and on the polysilicon 210 filled between the gate patterns 204. A bit line contact hole 223 for exposing the surface of the bit line contact pad 210b is then formed by partially etching the first interlayer dielectric 222, for example, through a photolithography process. Thereafter, tungsten 220a is continuously deposited on the bit line contact hole 223 and the first interlayer dielectric 222. As a result, the tungsten 220a is completely filled within the bit line contact hole 223. Silicon nitride 220b is deposited on the tungsten 220a. The silicon nitride 220b and the tungsten 220a are then partially etched to form a bit line structure 220, including the tungsten 220a and the silicon nitride 220b, for example, through a photolithography process.

A silicon nitride is then deposited on the bit line structure 220 and the first interlayer dielectric 222. A spacer structure 224 is formed on the sidewall portion of the bit line structure 220 through etching of the silicon nitride. The tungsten 220a of the bit line structure 220 is thus covered with the silicon nitride 220b of the mask layer and is surrounded by the silicon nitride of the spacer structure 224.

A second interlayer dielectric 230 is subsequently deposited on the bit line structure 220, the spacer structure 224 and the first interlayer dielectric 222. The second interlayer dielectric 230 includes silicon nitride and is deposited, for example, through a high-density plasma deposition process.

Referring now to FIG. 2C, the second interlayer dielectric 230 and the first interlayer dielectric 222 are etched to form a self-aligned contact hole 232 exposing the surface portion of the capacitor contact pad 210a. The etching is accomplished, for example, by using a difference between etching rates of the silicon nitride of the bit line structure 220 and the spacer structure 224 and the silicon oxide of the second interlayer dielectric 230 and the first interlayer dielectric 222.

As shown in FIG. 2D, a plug 234 for a lower electrode of the capacitor is filled within the self-aligned contact hole 232. The plug 234 for the lower electrode can be an amorphous silicon layer, a polycrystalline silicon layer, and/or the like. A single one of these layers may be formed or two or more layers can be deposited to form a composite layer.

Referring now to FIG. 2E, a node for a lower electrode 234a connected to the plug 234 and having a cylindrical shape is formed. Thus, a lower electrode including the plug 234 in the contact hole 232 and the node 234a is provided. The node 234a may be formed using the same material as the plug 234.

A method of forming the lower electrode including the plug 234 and the node 234a may include filling the plug 234 within the self-aligned contact hole 232. An oxide layer (not shown) may then be continuously formed on the second interlayer dielectric 230 and the plug 234. The oxide layer may be patterned to have a cylindrical shape. An electrode material for forming the node 234a is then deposited on the patterned oxide layer having a cylindrical shape. The oxide layer is etched to form the lower electrode having a cylindrical shape.

As shown in FIG. 2F, a reaction-preventing protection layer 236 is formed on the surface portion of the lower electrode having the cylindrical shape. The reaction preventing protection layer 236 is formed to limit and/or prevent the formation of an oxide layer at an interface of the lower electrode and the dielectric layer 237 during subsequent forming of the dielectric layer 237 and to limit and/or prevent the generation of a contact resistance of a metal wiring of the device. The reaction-preventing protection layer 236 may be a nitride layer. As discussed above, when the reaction-preventing protection layer 236 is formed at a high temperature, the phase of the lower electrode may be changed, which may adversely affect the contact resistance. Accordingly, for some embodiments of the present invention, the reaction preventing protection layer 236 is formed at a temperature of about 600° C. or less so that the phase change of the lower electrode and the related adverse effect on contact resistance may be limited or eliminated.

After forming the reaction-preventing protection layer 236, a dielectric layer 237 is formed on the reaction-preventing protection layer 236. The dielectric layer 237 may be formed by depositing the metal oxide as described above. The dielectric layer 237 may be, for example, a TiO₂ layer, an Al₂O₃ layer, a Y₂O₃ layer, a ZrO₂ layer, an HfO₂ layer, a BaTiO₃ layer, an SrTiO₃ layer and/or the like. A single layer structure of one of these layers may be used or two or more of these layers can be sequentially deposited to form the dielectric layer 237 as a composite layer.

In some embodiments of the present invention, no post-treatment process is carried out after forming the dielectric layer 237. In particular, the metal oxide dielectric layer 237 may be formed by chemical vapor deposition at a temperature of about 600° C. or less or by atomic layer deposition at a temperature of about 600° C. or less.

As shown in FIG. 2G, a conductive material is deposited on the dielectric layer 237 to form an upper electrode 238 of the capacitor. The upper electrode 238 may be an amorphous silicon layer, a polycrystalline silicon layer, an Ru layer, a Pt layer, an Ir layer, a TiN layer, a TaN layer, a WN layer and the like. As a result, a capacitor of an integrated circuit device is formed including the lower electrode 234, 234a, the dielectric layer 237 and the upper electrode 238.

In various embodiments of the present invention as described above, the cylindrical shape capacitor is formed at a temperature of about 600° C. or less. Therefore, a thermal damage during forming the capacitor can be reduced. In addition, as the dielectric layer may be formed as a metal oxide layer having a high dielectric constant, the storage capacity of the capacitor can be sufficiently increased for various applications. The reaction-preventing protection layer may facilitate the formation of the dielectric layer to provide a capacitor having a desired storage capacity.

The properties of a capacitor formed according to some embodiments of the present invention will now be further described with reference to a particular example.

Preparation of Sample 1:

A polycrystalline silicon layer was formed as a lower electrode on a substrate. A nitride layer was formed on the polycrystalline silicon layer as a reaction-preventing protection layer. The nitride layer was formed by an atomic layer deposition method at a temperature of about 550° C. An Al₂O₃ layer was then formed as a dielectric layer on the nitride layer. The Al₂O₃ layer was formed by the atomic layer deposition method at a temperature of about 450° C. A composite layer of TiN layer and a polycrystalline silicon layer was then formed on the Al₂O₃ layer as an upper electrode. The above-described processes provided sample 1.

Preparation of Sample 2:

Sample 2 was prepared through the same procedure as described above for sample 1 except that the nitride layer was formed by rapid thermal nitration at a temperature of about 750° C. and a heat treatment was implemented after forming the dielectric layer.

Measurements of Contact Resistance:

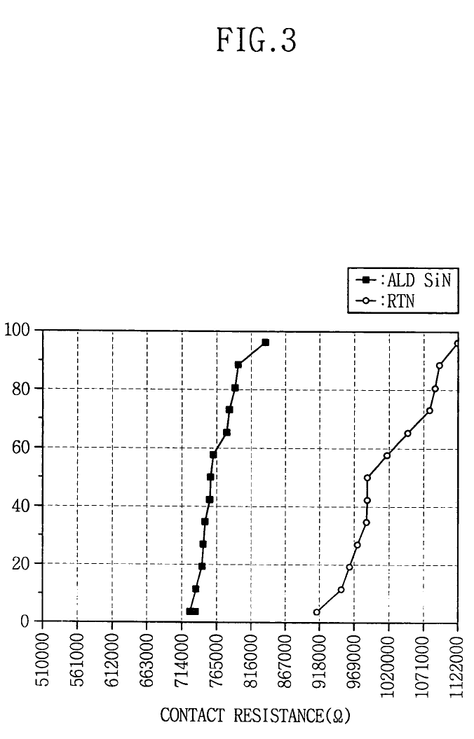

The contact resistances of sample 1 and sample 2 were measured. The results of these measurements are illustrated in FIG. 3. As shown in FIG. 3, the contact resistance of sample 1 is lower than that of sample 2. It is believed this indicates that a thermal damage is decreased when the capacitor is formed at a low temperature as with sample 1 as compared to sample 2.

Twin Bit Defect:

A twin bit defect refers to a contact between capacitor patterns through an inclination. When observing the twin bit defect of sample 1 and sample 2, the twin bit defect of sample 1 was found to be four per chip and the twin bit defect of sample 2 was found to be about 20 per chip. It is believed that this indicates that thermal damage can be decreased when the reaction-preventing protection layer is formed at a relatively low temperature.

As described above, a capacitor may be formed at a low temperature of about 600° C. or less. Therefore, a thermal damage to the capacitor and the contact resistance can be decreased. In addition, a metal oxide layer having a high dielectric constant may be advantageously used as the dielectric layer. For some embodiments of the present invention, an integrated circuit device having an improved reliability can, therefore, be manufactured.

In the drawings and specification, there have been disclosed typical preferred embodiments of the invention and, although specific terms are employed, they are used in a generic and descriptive sense only and not for purposes of limitation, the scope of the invention being set forth in the following claims.

What is claimed is:

1. A method of forming a capacitor on an integrated circuit comprising:
forming a lower electrode of the capacitor on an integrated circuit substrate;
forming a protection layer on the lower electrode at a temperature below a minimum temperature associated with a phase change of the lower electrode;
forming a dielectric layer on the protection layer, wherein the protection layer is configured to limit oxidation of the lower electrode during forming of the dielectric layer; and
forming an upper electrode of the capacitor on the dielectric layer.

2. The method of claim 1 wherein the first lower electrode comprises an amorphous silicon layer, a polycrystalline silicon layer and/or a composite layer thereof.

3. The method of claim 1 wherein the protection layer comprises a nitride layer.

4. The method of claim 3 wherein forming the protection layer comprises forming the nitride layer at a temperature of about 600° C. or less using a plasma nitration process.

5. The method of claim 3 wherein forming the protection layer comprises forming the nitride layer at a temperature of about 600° C. or less using a chemical vapor deposition process and/or an atomic layer deposition process.

6. The method of claim 3 wherein forming the protection layer comprises forming the nitride layer at a temperature of about 600° C. or less using a microwave-type deposition process.

7. The method of claim 1 wherein the dielectric layer comprises a metal oxide layer.

8. The method of claim 7 wherein the metal oxide layer comprises a TiO₂ layer, an Al₂O₃ layer, an Y₂O₃ layer, a ZrO₂ layer, an HfO₂ layer, a BaTiO₃ layer, an SrTiO₃ layer and/or a composite layer thereof.

9. The method of claim 7 wherein forming the dielectric layer comprises forming the metal oxide layer at a temperature of about 600° C. or less using a chemical vapor deposition process and/or an atomic layer deposition process.

10. The method of claim 1 wherein the protection layer comprises a silicon nitride layer.

11. The method of claim 1 wherein the upper electrode comprises an amorphous silicon layer, a polycrystalline silicon layer, an Ru layer, a Pt layer, an Ir layer, a TiN layer, a TaN layer, a WN layer and/or a composite layer thereof.

12. The method of claim 1 wherein the lower electrode comprises a cylindrical lower electrode and wherein forming a lower electrode comprises:
forming a lower structure on the integrated circuit substrate;
forming an insulation layer pattern having a contact hole on the lower structure;
forming a conductive plug in the contact hole;
forming an oxide layer patterned to have a cylindrical shape on the insulation layer pattern and the plug;
forming a conductive layer for the lower electrode on the oxide layer; and
removing the oxide layer to form the cylindrical lower electrode.

13. The method of Claim- 12 wherein forming the protection layer comprises forming the protection layer on the cylindrical lower electrode.

14. A method of forming a capacitor comprising:
forming a first conductive layer on a substrate;
forming a reaction-preventing layer on the first conductive layer to prevent an oxidation at a temperature of not generating a phase change of the first conductive layer;
forming a dielectric layer on the reaction preventing layer; and
forming a second conductive layer on the dielectric layer.

15. The method of claim 14 wherein the first conductive layer is an amorphous silicon layer, a polycrystalline silicon layer or a composite layer thereof.

16. The method of claim 14 wherein the reaction-preventing layer is a silicon nitride layer.

17. The method of claim 16 wherein the silicon nitride layer is formed by a plasma nitration method at a temperature of about 600° C. or less.

18. The method of claim 16 wherein the silicon nitride layer is formed by a chemical vapor deposition method at a temperature of about 600° C. or less or an atomic layer deposition method at a temperature of about 600° C. or less.

19. The method of claim 16 wherein the silicon nitride layer is formed by a microwave-type deposition method at a temperature of about 600° C. or less.

20. The method of claim 14, wherein the dielectric layer is a metal oxide layer.

21. The method of claim 20 wherein the metal oxide layer is at least one selected from the group consisting of a TiO₂ layer, an Al₂O₃ layer, an Y₂O₃ layer, a ZrO₂ layer, an HfO₂ layer, a BaTiO₃ layer, an SrTiO₃ layer and a composite layer thereof.

22. The method of claim 20 wherein the metal oxide layer is formed by a chemical vapor deposition method at a temperature of about 600° C. or less or by an atomic layer deposition method at a temperature of about 600° C. or less.

23. The method of claim 14 wherein the second conductive layer is an amorphous silicon layer, a polycrystalline silicon layer, a Ru layer, a Pt layer, an Ir layer, a TiN layer, a TaN layer, a WN layer and a composite layer thereof.

24. A method of forming a capacitor comprising:
forming an insulation layer pattern having a contact hole on a substrate having a lower structure;
forming a first conductive layer continuously on a sidewall portion and a bottom portion of the contact hole and on the surface of the insulation layer pattern;
removing the first conductive layer formed on the surface portion of the insulation layer pattern;
removing the insulation layer pattern to allow the first conductive layer to remain on the sidewall portion and the bottom portion of the contact hole to form a cylindrical lower electrode;
forming a reaction-preventing layer on the cylindrical lower electrode for preventing an oxidation at a temperature of not generating a phase change of the lower electrode;
forming a dielectric layer on the reaction preventing layer; and
forming a second conductive layer on the dielectric layer as an upper electrode.

25. The method of claim 14 wherein the first conductive layer is an amorphous silicon layer, a polycrystalline silicon layer or a composite layer thereof.

26. The method of claim 14 wherein the reaction preventing layer is formed by a plasma nitration method at a temperature of about 600° C. or less, a chemical vapor deposition method at a temperature of about 600° C. or less or an atomic layer deposition method at a temperature of about 600° C. or less.

27. The method of claim 14 wherein the dielectric layer is at least one selected from the group consisting of a TiO₂ layer, an Al₂O₃ layer, a Y₂O₃ layer, a ZrO₂ layer, an HfO₂ layer, a BaTiO₃ layer, an SrTiO₃ layer and a composite layer thereof.

28. The method of claim 24 wherein the dielectric layer is formed by a chemical vapor deposition method at a temperature of about 600° C. or less or by an atomic layer deposition method at a temperature of about 600° C. or less.

29. The method of claim 24 wherein the second conductive layer is one of an amorphous silicon layer, a polycrystalline silicon layer, an Ru layer, a Pt layer, an Ir layer, a TiN layer, a TaN layer, a WN layer and a composite layer thereof.

30. The method of claim 24 wherein the lower structure includes a contact plug connected to the lower electrode.
